(19) United States
(12) Patent Application Publication
(10) Pub. No.: US 2026/0280576 A1
(43) Pub. Date: Sep. 17, 2026

(54) METHOD AND APPARATUS FOR DETECTING JITTER

(71) Applicant: Analog Devices International Unlimited Company, Limerick (IE)

(72) Inventors: Roberto S. Maurino, Torino (IT); Naiqian Ren, Limerick (IE)

(21) Appl. No.: 19/079,259

(22) Filed: Mar. 13, 2025

(51) Int. Cl. H03M 1/08; H03M 1/06

(52) U.S. Cl. CPC H03M 1/0836; H03M 1/0626

(57) ABSTRACT

The present disclosure provides methods and apparatus for detecting jitter on a clock signal and/or electronic component. An example method for detecting jitter on a clock signal comprises: operating a digital-to-analog converter, DAC, with a clock signal, the clock signal having noise comprising jitter to be detected; feeding an output of the DAC to an input of a CT integrator; quantizing a signal generated from the output of the CT integrator; filtering, by a low pass filter, the quantized signal such that the filtered output signal is directly proportional to the jitter in the clock signal; and detecting jitter based on the filtered output signal.

### FIELD

The present disclosure generally relates to methods and systems for detecting jitter on an electronic component. More specifically, but not exclusively, the present disclosure relates to methods and systems for detecting jitter on an electronic component through the use of a digital-to-analog converter (DAC), a continuous time (CT) integrator and a low pass filter.

### BACKGROUND

Jitter in electronic circuits refers to the small, rapid variations in the timing of a signal, often caused by factors like electromagnetic interference or crosstalk. These timing deviations can have several disadvantages. For instance, jitter can lead to data integrity issues, resulting in corrupted data or increased bit error rates. It can also degrade the quality of audio and video signals, which is particularly problematic for multimedia applications. Additionally, high levels of jitter can disrupt the synchronization of clock signals in embedded systems, potentially causing system failures. In high-speed digital systems, jitter can affect the precision of timing measurements, impacting the overall system accuracy.

When it comes to analog to digital conversion, jitter affects the timing of when the analog signal is sampled. Ideally, samples should be taken at precise intervals, but jitter causes variations in these intervals, leading to inaccuracies in the digitized signal. This is especially problematic for high-frequency signals, where even small timing errors can result in significant distortion. For digital to analog conversion, jitter impacts the timing of when digital values are converted back to analog signals. If the timing of these conversions is inconsistent, it can introduce noise and distortion into the analog output. This is particularly critical in audio applications, where jitter can degrade sound quality

Certain data converter architectures, such as continuous time sigma delta (CTSD), are more sensitive to clock jitter. This is the case as in CTSDs, the stepped output of the feedback DAC is constantly being integrated, which means any clock signal uncertainty can introduce error into the integrator signal. In practice this can cause the following issues:
The precision of ADC conversion results may fall short of expectations. The root causes of these quality problems may include poor-quality clock signals, system design, layout, and interference. Given the multitude of factors that can affect measurement precision, isolating the issue to the clock can be challenging.
Some products, particularly in the instrumentation market, support external clock inputs. In these cases, the equipment provider has no control over the quality of the external clock sources but can be blamed for not meeting specified measurement precision. Identifying the source of the problem in such situations can be challenging and it also be resource-consuming by the equipment provider.
During system deployment, factors such as device installation, operating environment and usage profile can impact the clock jitter level. The change is not easily detectable and can result in degradation of performance.

### SUMMARY OF THE DISCLOSURE

Therefore, there is a need for an improved method and system for accurately detecting jitter on an electronic component. In other words, there may be a need to provide a mechanism that is integrated on the data converter that can quantify and report the jitter level on the converter clock.

that the present approach may be implemented on an electronic component such as a data converter, to allow the electronic component to perform a self-check on the jitter noise level of its clock signal.

In a first aspect, there is provided a method of detecting jitter on a clock signal or electronic component, the method comprising: operating an input of a digital-to-analog converter, DAC, with a clock signal, the clock signal having noise comprising jitter to be detected; feeding an output of the DAC to an input of a CT integrator; quantizing a signal generated from the output of the CT integrator; filtering, by a low pass filter, the quantized signal such that the filtered output signal is directly proportional to the jitter in the clock signal; and detecting jitter based on the filtered output signal.

The method for detecting jitter on a clock signal provides the advantage of enabling better understanding of noise present on the clock signal. The clock signal may be received from an electronic component and surrounding environment e.g. if noise is detected on the electronic component being able to detect the jitter thereon gives an understanding of where the noise may be arising. This can aid in the removal or reduction of said noise. Therefore, the method can reduce the time taken to find the source of the jitter and improve the ease of detection.

Moreover, the method can be used to detect noise and other anomalies in the circuit that either induces or correlates with the clock jitter. i.e. it can be presented as a noise or/and EMI detector.

In a second aspect, there is provided an apparatus for detecting jitter on a clock signal, the apparatus comprising: a first digital-to-analog converter, DAC, configured to be operated by a clock signal, the clock signal comprising jitter to be detected; a CT integrator configures to receive an output from the first DAC; a quantizer configured to quantize a signal generated from the output of the CT integrator; and a low pass filter configured to filter the quantized signal such that the filtered output signal is directly proportional to the jitter in the clock signal.

The apparatus for detecting jitter on a clock signal or electronic component provides the advantage of enabling better understanding of the electronic component and the environment it is experiencing e.g. if noise is detected on the electronic component being able to detect the jitter thereon gives an understanding of where the noise may be arising. This can aid in the removal or reduction of said noise. Therefore, the method can reduce the time taken to find the source of the jitter and improve the ease of detection.

In a third aspect, there is provided a transducer, the transducer comprising: a digital-to-analog converter, DAC, configured to be driven by an input signal, which may be a clock signal, from an environment, the input signal comprising jitter; a CT integrator configured to receive an output of the DAC; a quantizer configured to quantize an output of the CT integrator; and a low pass filter configured to filter the quantized output such that the filtered output signal is directly proportional to the jitter in the input; wherein the transducer is configured to determine a property of the environment based on the filtered output signal.

The transducer provides the advantage of utilizing the detected jitter on an input signal to detect an environmental property. For example, the jitter on the input signal may vary with temperature i.e. the increase in jitter on the input signal is proportional to the increase in temperature of the component supplying the input signal. Therefore, the detection of the jitter can enable the detection of the environmental temperature, or the change in environmental change. Thus, the transducer provides the advantage of enabling the detection of numerous environmental properties, including but not limited to: temperature, pressure, displacement, velocity, acceleration, force, flow, sound, light, humidity, magnetic field etc.

Further features and advantages will be apparent from the appended claims.

### BRIEF DESCRIPTION OF THE FIGURES

Further features and advantages of the present disclosure will become apparent from the following description, presented by way of example only, and with reference to the accompanying drawings, wherein like reference numerals refer to like parts, and wherein:

FIG. 1a shows an example schematic diagram of an ADC system;

FIG. 1b shows an example graph showing the relationship between RMS Jitter and RMS noise on the ADC system of FIG. 1a;

FIG. 2 shows an example block diagram of the apparatus, in accordance with the present disclosure;

FIG. 3 shows an example schematic diagram of the apparatus, in accordance with the present disclosure;

FIG. 4 shows an example schematic diagram of the apparatus, in accordance with the present disclosure;

FIG. 5 shows an example flow diagram representing the method for detecting jitter associated with the apparatus of FIG. 4, in accordance with the present disclosure;

FIG. 6 shows a further example schematic diagram of the apparatus, in accordance with the present disclosure;

FIG. 7 shows a further example flow diagram representing the method for detecting jitter associated with the apparatus of FIG. 6, in accordance with the present disclosure; and

FIG. 8 shows a further example block diagram of the apparatus, in accordance with the present disclosure.

### DETAILED DESCRIPTION

The present disclosure provides methods and systems for detecting jitter on a clock signal and/or electronic component in an accurate and reliable manner.

Further, the methods and systems seek to enable better understanding of the clock signal and/or electronic component and the environment it is experiencing e.g. if noise is detected on the clock signal and/or electronic component, being able to detect the jitter thereon gives an understanding of where the noise may be arising. This can aid in the removal or reduction of said noise. Therefore, the method can reduce the time taken to find the source of the jitter and improve the ease of detection.

More specifically, the present disclosure provides a method of detecting jitter on a clock signal, wherein the method performs the following steps: (a) operating a digital-to-analog converter, DAC, with a clock signal, the clock signal having noise comprising jitter to be detected, (b) feeding an output of the DAC to an input of a CT integrator, (c) quantizing a signal generated from the output of the CT integrator, (d) filtering, by a low pass filter, the quantized signal such that the filtered output signal is directly proportional to the jitter in the clock signal, (e) detecting jitter based on the filtered output signal.

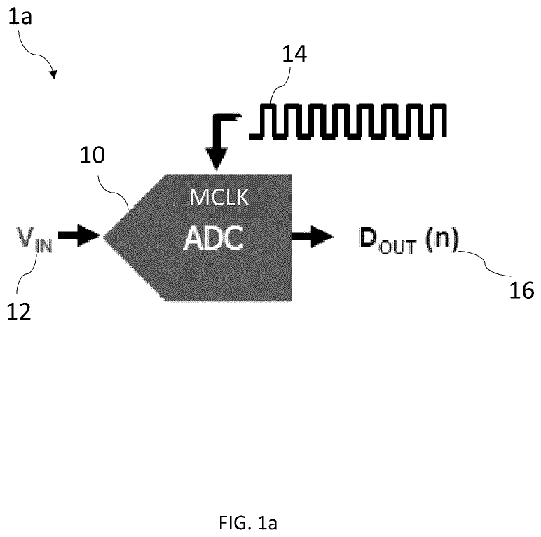

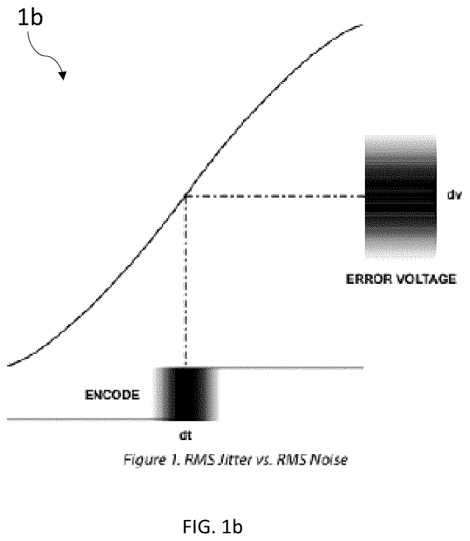

The present inventors have recognized that this method will aid in providing a robust and reliable method of detecting jitter on a clock signal. The importance of this will now be discussed in relation to FIGS. 1a and 1b, in accordance with a comparative approach.

FIG. 1a shows an example schematic diagram of an ADC system 1a, in accordance with the comparative approach. FIG. 1a shows an ADC system 1a comprising an ADC 10 with a voltage input, Vin 12, a master clock signal 14, and a digital voltage output, Dout (n) 16. The ADC 10 is supplied with a square wave master clock signal 14 from an external clock device, source or electronic component. The input signal 12, referred to as Vin, is sampled by the ADC 10, which uses the master clock 14 to sample the input Vin. The output signal 16, known as Dout (n), is generated based on the sampled input signal 12.

In relation to FIG. 1a, FIG. 1b shows an example graph detailing the relationship between root mean square (RMS) Jitter and RMS noise on the ADC system 1a of FIG. 1a, in accordance with the prior art.

In the context of an ADC system 1a, RMS jitter refers to the root mean square of the variations in the timing of a signal. Ideally, samples should be taken at precise intervals, but jitter causes variations in these intervals, leading to inaccuracies in the digitized signal 16. This is especially problematic for high-frequency signals, where even small timing errors can result in significant distortion. RMS noise, on the other hand, is the root mean square of the noise present in the system. Noise can be introduced by various factors, including jitter. In an ADC system 1a, noise can degrade the quality of the digitized signal 16, leading to data integrity issues and increased bit error rates.

The graph in FIG. 1b shows how these two parameters are related in the ADC system 1a. As RMS jitter increases, the RMS noise also increases, indicating that higher jitter leads to more noise in the ADC system 1a and more noise on the digital output signal 16. This relationship highlights the importance of minimizing jitter to ensure the accuracy and quality of the digital output signal 16 in ADC systems 1a.

Therefore, there is a further need for a system and method that enables users to detect and isolate jitter noise, improving the ease of detection and reducing the time taken to find the source of the jitter.

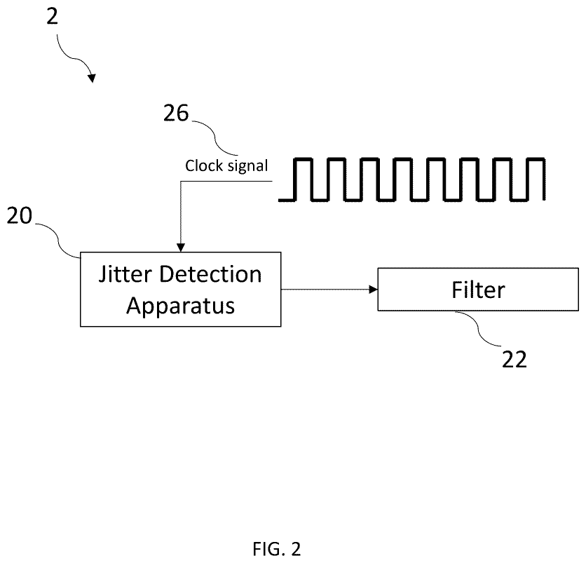

The present disclosure seeks to provide solutions to the aforementioned problem. The solutions, in accordance with the present disclosure, will now be discussed in relation to FIGS. 2-8.

The present inventors have recognised that by low pass filtering a quantized signal by a CT integrator, then advantageously, the filtered output signal is directly proportional to jitter in the clock signal. This enables them to detect jitter based on the filtered output signal, the present disclosure provides a method of operating an apparatus, wherein the operation enables the mapping of a filtered output to the jitter in the clock signal based on an operation of the DAC, thereby allowing for precise detection and quantification of jitter in various electronic components and systems.

In addition to the advantages already mentioned, there are several other benefits of the present disclosure. Firstly, this method helps in better understanding the noise present on the clock signal. By detecting jitter, it becomes easier to identify and reduce noise, leading to improved signal quality. Secondly, the apparatus for detecting jitter provides a better understanding of the clock signal, which may be from an electronic component and/or its environment. This can aid in the detection of jitter noise, thereby improving the accuracy of noise reduction detection. Thirdly, a transducer can utilize the detected jitter to determine various environmental properties such as temperature, pressure, displacement, velocity, acceleration, force, flow, sound, light, humidity, and magnetic field. This makes the method versatile and useful in a wide range of applications.

Ways in which to achieve the abovementioned advantages will be described in relation to FIG. 2-8. One solution of the present disclosure involves placing a DAC, a CT integrator and ADC in a feedback loop. In this scenario, an average of the DAC output is zero at the input of the CT integrator when clock signal comprises no jitter or wherein an average of the DAC output deviated from zero by an offset at the input of the CT integrator. Another solution of the present disclosure involves feeding a known square wave input to an input pin of the CT integrator. Again, an average of the DAC output is zero at the input of the CT integrator when clock signal comprises no jitter or wherein an average of the DAC output deviated from zero by an offset at the input of the CT integrator.

FIG. 2 shows an example block diagram of the apparatus, in accordance with the present disclosure. The block diagram of the apparatus 2 is designed to detect jitter in a clock signal 26 and comprises several key components: a jitter detection apparatus 20, and a clock signal 26, and may include a filter 22. The jitter detection apparatus 20 is responsible for identifying and measuring the jitter present in the clock signal 26. Jitter refers to the small, rapid variations in the timing of a signal, which can lead to inaccuracies and noise in electronic systems. The filter 22 processes the signal to remove unwanted noise, isolating the jitter component, making it easier to measure and analyse. The clock signal 26 provides the timing reference for the system, and any jitter in this signal can affect the performance of the entire system, making it crucial to detect and minimize.

In more detail, the apparatus 2 for detecting jitter on a clock signal may comprise a first digital-to-analog converter, DAC, within the jitter detection apparatus 20 which may be configured to be operated by a clock signal 26, the clock signal 26 comprising jitter to be detected; a CT integrator within the jitter detection apparatus 30 configured to receive an output from the first DAC; a quantizer within the apparatus detection apparatus 20 configured to quantize a signal generated from the output of the CT integrator; and a filter 22 which may be a low pass filter configured to filter the quantized signal such that the filtered output signal is directly proportional to the jitter in the clock signal 26.

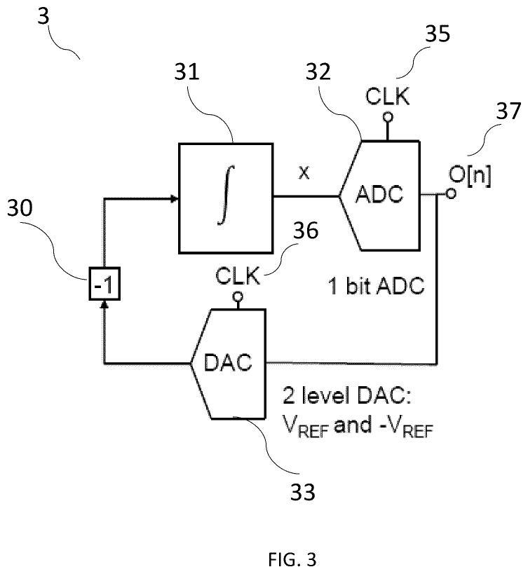

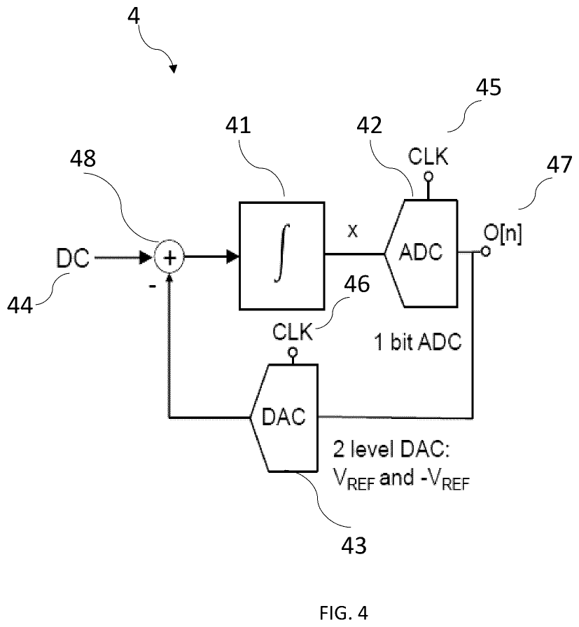

An example schematic of the apparatus 2 of FIG. 2 is shown in FIGS. 3 and 4. In this regard, FIGS. 3 and 4 show an example schematic diagram 3, 4 of the apparatus, in accordance with the present disclosure. The apparatus 3 comprises an inverting block 30, a CT integrator 31, a quantizer 32 which may be an ADC and a DAC 33. The apparatus 3 includes, a quantizer clock signal 35, a DAC clock signal 36 which includes the jitter to be detected and an output signal 37.

The inverting block 30 provides the negative feedback loop between the input signal into the CT integrator 31 and the output signal from the DAC 33. The output of the CT integrator 31 is coupled to the quantizer 32 e.g. the ADC. In turn, the quantizer 32 is coupled to the input of the DAC 33. The DAC 33 may be a 2 level DAC which switches between Vref and −Vref. The output of the DAC 33 is fed back to the input of the CT integrator 31 via the negative node 30. In some embodiments, an average of the DAC 33 output may be zero at the input of the CT integrator 31 when clock signal 36 comprises no jitter or an average of the DAC 43 output may deviate from zero by an offset at the input of the CT integrator 31.

With an ideal clock, the charge from the feedback DAC 33 is forced to zero, thus the output 37 of the ADC 32 is a sequence of alternating ones and zeros. In the presence of clock jitter, the charge packets from the DAC 33 become jitter-dependent, leading to change at ADC output 37 with uneven ones and zeros. The jitter level can be measured by processing the ADC output 37 bit stream.

FIG. 4 provides an example schematic diagram of the apparatus 4 in accordance with the apparatus 2 of FIG. 2. Moreover, the example schematic diagram contains many of the components provided in the example schematic diagram apparatus 3 of FIG. 3.

The apparatus 4 comprises a summation node 48, a CT integrator 41, a quantizer 42 which may be an ADC and a DAC 43. The apparatus 4 includes an input signal 44, that may be a DC input signal, that feeds into the summation node 48, a quantizer clock signal 45, a DAC clock signal 46 which includes the jitter to be detected and an output signal 47.

The summation node 48 sums the input signal 44 and the output signal from the DAC 43. The output of the summation node 48 is coupled to the input of the CT integrator 41. The output of the CT integrator 41 is coupled to the quantizer 42 e.g. the ADC. In turn, the quantizer 42 is coupled to the input of the DAC 43. The DAC 43 may be a 2 level DAC which switches between Vref and −Vref. The output of the DAC 43 is fed back to the input of the CT integrator 41 via the summation node 40. In some embodiments, an average of the DAC 43 output may be zero at the input of the CT integrator 41 when clock signal 46 comprises no jitter or an average of the DAC 43 output may deviate from zero by a known offset at the input of the CT integrator 41.

With an ideal clock, the DAC 43 is forced to create an output patten with the average value equal to the inverse of the input value. In the presence of clock jitter, the charge packets from the DAC 43 become jitter-dependent, leading to deviation at the ADC 42 output. The jitter level can be measured by processing the ADC 42 output bit stream 47.

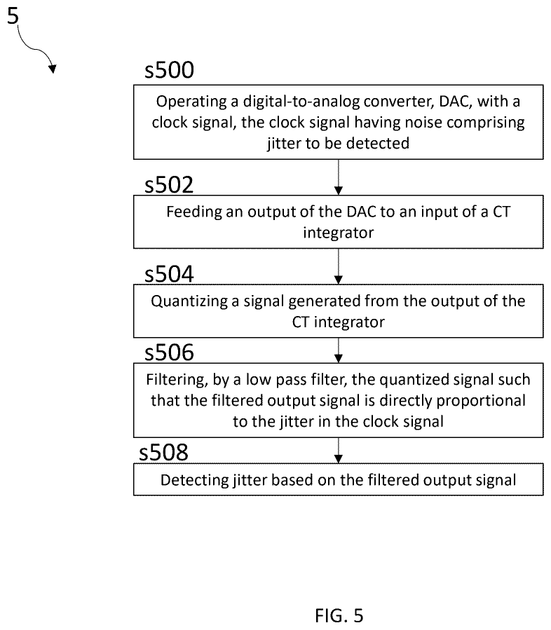

The apparatuses 3 and 4 operate in accordance with the flow diagram 5 shown in FIG. 5. FIG. 5 provides an example flow diagram representing the method for detecting jitter associated with the apparatus of FIGS. 3 and 4, in accordance with the present disclosure. The method of FIG. 5 will be discussed relative to the apparatus 4 of FIG. 4; however, it can also be applied to apparatus 3 of FIG. 3.

The method for detecting jitter on a clock signal or electronic component, as shown in the flow diagram 5 of FIG. 5, begins with s500 of operating a digital-to-analog converter, DAC 43, with a clock signal 46, the clock signal 46 having noise comprising jitter to be detected. The clock signal 46 may be a square wave clock signal. The clock signal 46 may be the same clock signal as used for other components of the apparatus or system or it may be an entirely isolated clock signal.

A person having ordinary skill in the art will recognize that FIG. 4 implements a first order CT sigma delta with the input set to zero. In some examples, the apparatus 4 may be adapted and the method may optionally include implementing a CT sigma delta modulator and shorting an input pin of the CT sigma delta modulator such that the input to the CT sigma delta modulator is zero.

Next, in s502, the output of the DAC 43 is fed into the input of a CT integrator 41. The output of the DAC 43 may be fed into the input of the CT integrator 41 via the summation block 48. If this is the case, then the summation block 48 will sum the input signal 44 and the output signal of the DAC 43. The output of the DAC 43 may be Vref or −Vref if the DAC 43 is a two-level DAC.

Then, in s504, the signal generated from the output of the CT integrator 41 is quantized by the quantizer 42. In some embodiments, the quantizer 42 may be an ADC, as shown in FIG. 4. If the DAC is only two level, the ADC can be implemented as simple comparator for a 1-bit A/D conversion.

Next, in s506, the quantized signal from s504 is filtered, by a low pass filter, such that the filtered output signal is directly proportional to the jitter in the clock signal 46. Essentially, the low pass filter removes the large high-frequency components of the quantization noise, leaving behind a signal that accurately reflects the variations (jitter) in the clock signal 46. In other words, the filtering helps in isolating the low-frequency components, which are more indicative of the clock jitter. This filtered signal can then be analyzed to determine the extent of jitter present in the clock signal 46. In some examples, the filtering of the quantized signal may comprise digital filtering.

Additionally, dithering can be applied, whereby a small amount of random noise is added to the signal before quantization to decorrelate the quantization noise from the signal, resulting in a more uniform noise distribution. Lastly, advanced digital filtering techniques can be utilized to isolate and eliminate quantization noise from the signal, thereby improving its overall quality and fidelity.

In other examples, the filtered output signal may be processed to find a root mean square, RMS, value for the filtered output signal and/or to average the filtered output signal using integration.

Finally, in s508, the filtered output signal from s506 is used to detect the jitter in the output signal which in turn enables the detection of the jitter on the original clock signal 46.

In some examples, the final detection of the jitter in the clock signal may be achieved through applying a scale factor to express the filtered output signal as a clock jitter level in time, frequency or phase units.

Optionally, following s508, the filtered output signal may be further processed to determine the presence of jitter and/or a quantity of jitter in the clock signal. This additional processing can involve several methods. For instance, a frequency analysis of the filtered signal can be performed to isolate and quantify the jitter components. Alternatively, the filtered signal can be passed through a digital signal processor (DSP) to apply advanced filtering techniques or algorithms specifically designed for jitter detection. Each of these methods provides a different approach to thoroughly analyze the jitter characteristics, offering a comprehensive understanding of the clock signal's stability.

Further, there may be further steps to validate or verify the presence of or level of jitter within the clock signal. For example, jitter in the clock signal may be verified by verifying that the input signal comprises a predetermined level of jitter based on measuring an amplitude of the filtered output signal. Therefore, the clock signal would only be said to contain jitter if the amplitude of the filtered output signal indicative of jitter on the clock signal was above a predetermined level e.g. threshold amplitude level. This predetermined level or threshold amplitude level may be selectable by the user.

Similarly, the method may include generating a confidence coefficient using the filtered output signal indicative of the level of jitter present in the clock signal. For example, the confidence level might be computed based on the amplitude fluctuations observed in the filtered signal. If the amplitude variations are minimal, the confidence coefficient may be high, indicating a stable clock signal with minimal jitter. Conversely, if significant amplitude variations are detected, the confidence coefficient may be lower, reflecting a higher level of jitter and thus a less stable clock signal. Another approach to determining the confidence level could involve statistical analysis of the jitter characteristics over a given time period. By analyzing the variance and standard deviation of the filtered signal, the system may produce a confidence level that quantifies the consistency of the clock signal. A low variance may result in a higher confidence level, signifying reliable clock performance, while a high variance may lower the confidence level, suggesting more pronounced jitter.

The method for detecting a jitter on a clock signal in accordance with the flow diagram 5 of FIG. 5 can contain a number of additional optional steps.

One optional step comprises implementing a CT sigma delta modulator and shorting the input pin of the CT sigma delta modulator such that the input to the CT sigma delta modulator is zero. When this is the case, the CT sigma delta loop will force the output of the quantizer 42 e.g the ADC, to match the input. In turn, this may convert the clock signal 46 into current pulses of duration Ts, and amplitude

$$\frac{+}{-} \frac{{V}_{R E F}}{R}$$

causing charge packets of

$$\frac{+}{-} \frac{{V}_{R E F} * {T}_{s}}{R}$$

to be injected into the CT integrator 41, that average out to zero, wherein R is a resistance value of an associated electronic component and VREF is a reference voltage of the associated electronic component.

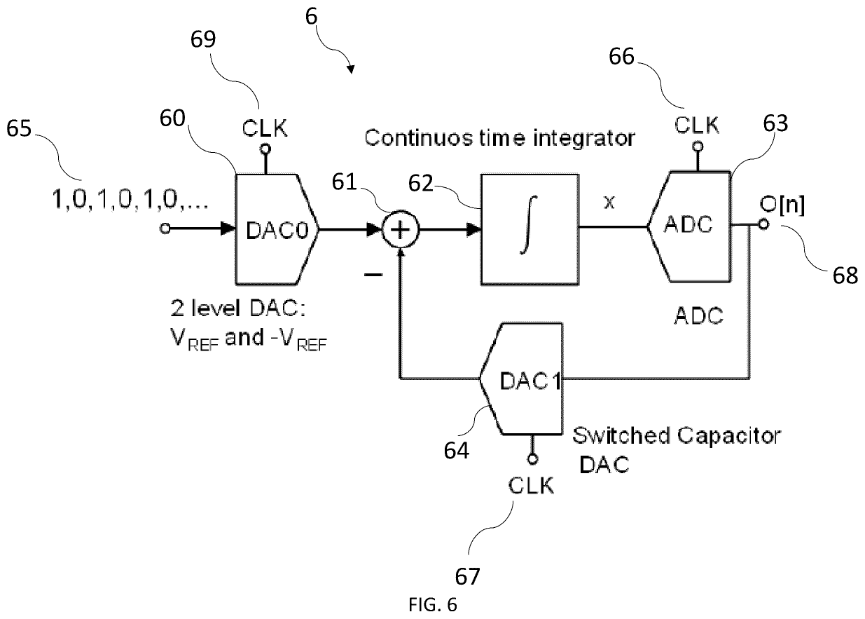

A further embodiment of the present disclosure is provided in FIG. 6. FIG. 6 shows a further example schematic diagram of the apparatus 6, in accordance with the present disclosure. The apparatus 6 for detecting jitter on a clock signal comprises a summation node 61, a CT integrator 62, a quantizer 63 e.g. an ADC, a feedback DAC 64 (also discussed as a first DAC) and an optional input DAC 60 (also discussed as a second DAC). The apparatus 6 comprises an input signal 65 which may be a square wave input signal as shown in FIG. 6. Further, the quantizer 63 has a clock signal 66 and the DAC 64 has a clock signal 67. The quantizer clock signal 66 and the first DAC clock 67 may be the same or independent to the DAC clock signal 69. Finally, the apparatus 6 comprises an output signal, O[n] 68.

Various arrangements may be applicable. For example, the ADC, first DAC and CT integrator may be configured to form a continuous time delta sigma, CTSD, modulator with a switched capacitor feedback DAC DAC1.

The input signal 65 is coupled to an input of the input DAC 60. The output of the input DAC 60 is coupled to the summation node 61 along with the feedback output from the feedback DAC 64. The output of the summation node 61 is coupled to the input of the CT integrator 62. The output signal of the CT integrator 62 is coupled to the quantizer 63. The output of the quantizer 63 is the output signal 68, but the output of the quantizer is also coupled to the input of the feedback DAC 64. In other words, the feedback DAC 64 is operated using the output of the quantizer 63 e.g. the ADC. Finally, the output of the feedback DAC 64 is coupled to the summation node 61 (as previously mentioned) such that the output of the feedback DAC 64 is coupled to the input of the CT integrator 62 via the summation node 61. In some embodiments, an average of the feedback DAC 64 output may be zero at the input of the CT integrator 62 when clock signal 69 comprises no jitter or an average of the DAC 64 output may deviate from zero by a known offset at the input of the CT integrator 62.

It is worth noting that one or more of the feedback DAC 64 and the input DAC 60 may be continuous time DACs.

In some examples, the clock signal 69 comprising the jitter to be detected may be supplied by an electronic component, the electronic component being configured to supply the clock signal to operate the first DAC 64. Said electronic component may be one or more of an analog-to-digital converter, ADC, a digital-to-analog converter, DAC, a phase-locked loop, PLL, a Frequency Synthesizer, a field-programmable gate array, FPGA, a central processing unit, CPU, a microcontroller, MCU, a digital signal processor, DSP, a Network interface/transceiver, a wireless transceiver, a clock generators/buffer, an application-specific integrated circuit, ASIC, and a sensor. Moreover, the electronic component and the CT integrator 62 may be arranged on the same die or package.

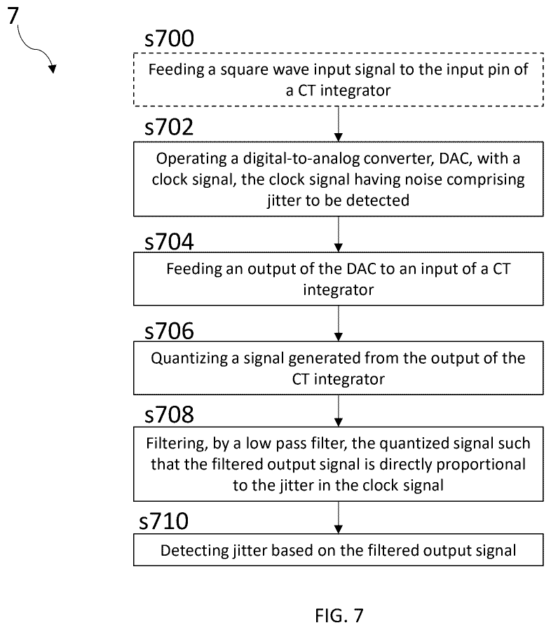

The apparatus 6 of FIG. 6 is operated in accordance with the method for detecting jitter in a clock signal as provided in the flow diagram 7 of FIG. 7.

The method of detecting jitter in a clock signal may begin with s700, wherein a square wave input signal 65 is fed into an input pin of a CT integrator 62. However, other input signals may be used for the input signal 65.

Next, in s702, a DAC 60 is operated with a clock signal 69 wherein the clock signal 69 comprises jitter to be detected. The clock signal 69 may be a square wave clock signal. The clock signal 69 may be the same clock signal as used for other components of the apparatus or system such as the quantizer clock signal 66 or or feedback DAC clock 67 or it may be an entirely isolated clock signal.

Next, in s704, the output of the DAC 64 is fed into the input of a CT integrator 62. The output of the DAC 64 may be fed into the input of the CT integrator 62 via the summation block 61. If this is the case, then the summation block 61 will sum the input signal 65 and the output signal of the DAC 64. The output of the DAC 64 may be Vref or −Vref if the DAC 64 is a two-level DAC.

Then, in s506, the signal generated from the output of the CT integrator 62 is quantized by the quantizer 63. In some embodiments, the quantizer 63 may be an ADC, as shown in FIG. 6.

Next, in s708, the quantized signal from s706 is filtered, by a low pass filter, such that the filtered output signal is directly proportional to the jitter in the clock signal 69. Essentially, the low pass filter removes the high-frequency components of the quantization noise signal, leaving behind a signal that accurately reflects the variations (jitter) in the clock signal 69. In other words, the filtering helps in isolating the low-frequency components, which are more indicative of the clock jitter. This filtered signal can then be analyzed to determine the extent of jitter present in the clock signal 69.

Finally, in s710, the filtered output signal from s708 is used to detect the jitter in the output signal which in turn enables the detection of the jitter on the original clock signal 69.

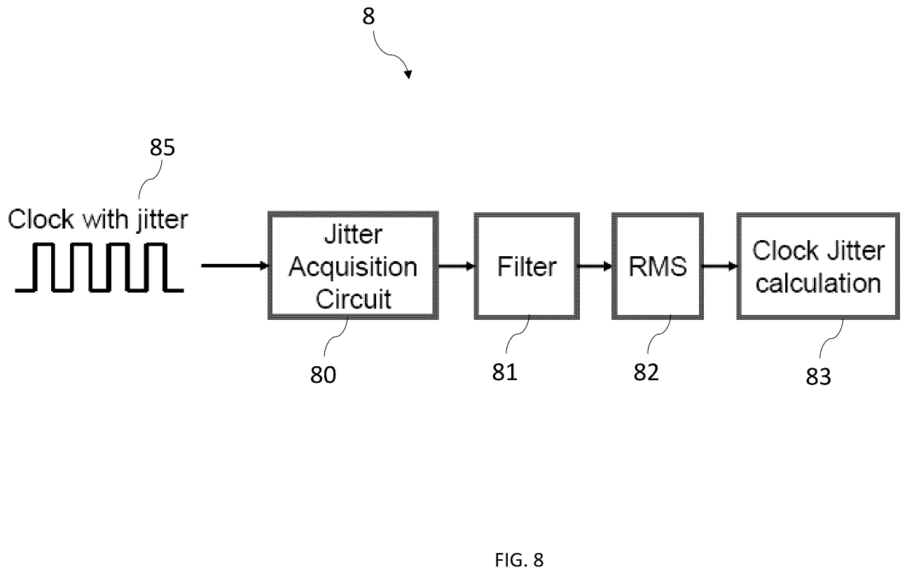

FIG. 8 relates to a further example block diagram of apparatus for detecting jitter on a clock signal, in accordance with the present disclosure. The flow diagram 8 comprises a jitter acquisition circuit 80, a digital filter 81, an RMS block 82 and a clock jitter calculation block 83. The block diagram 8 further includes a clock signal 85 that includes jitter to be detected, the clock signal 85 being coupled to the jitter acquisition circuit 80 The jitter acquisition circuit 80 may relate to any of apparatus 3, 4 or 6 as presented in FIGS. 3, 4 and 6.

The embodiment of FIG. 8 provides a new solution that can be implemented on a data converter, to allow the converter to perform self-check on the jitter noise level of its clock.

Alternatively, the scheme may take advantage of the known fact that CTSD is sensitive to clock jitter. It involves using a simple first order (or higher) CTSD modulator as the jitter acquisition circuit 80 (wherein the input may be shorted) running off a clock signal 85 comprising jitter. The noise level at the CTSD output, which is directly proportional to the clock jitter, is being measured to quantify the clock jitter noise level in the clock signal 85.

Optionally, assume we have a single bit first order CTSD that can output 0 or 1, and that the DAC is resistive with resistance value R and reference voltage Vref. With zero input, the charge from the feedback DAC is forced to zero, thus the output of the ADC is a sequence with, on average, the same number of ones and zero.

The feedback DAC of the CTSD converts 1 and 0 into current pulse of duration Ts (Ts=sampling period) and amplitude

$$\frac{{V}_{R E F}}{R} and - \frac{{V}_{R E F}}{R} ,$$

thus injecting packets of charge

$$\frac{{V}_{R E F} * T s}{R} and - \frac{{V}_{R E F} * T s}{R}$$

of into the integrator.

In the presence of clock jitter, the charge packets from the DAC become jitter dependent. An additional error charge signal is introduced given by:

$$Echarge Jitter = ( O [ n ] - O [ n - 1 ] ) * \frac{Vref}{R} * t j [ n ]$$

Where tj[n] is the jitter at the n clock edge, corresponding to the transition from O[n−1] to O[n], and O[n] is the input of the DAC corresponding to the quantizer output.

This is equivalent to having an input voltage error of:

$$Evoltage Jitter - ( O [ n ] - O [ n - 1 ] ) * Vref * t j [ n ]$$

For a single bit CTSD the RMS in-band noise voltage associated to Evoltage Jitter can be found to be

$$Evoltage power = \frac{V r e f * {σ}_{tj}}{T s} * \sqrt{\frac{0.8}{OSR}}$$

Where σₜⱼ is the rms jitter, OSR is the oversampling ratio and 0.8 is the probability of O[n] transitioning for a first order CTSD.

The apparatus and methods provided in the present disclosure are applicable, but not limited to, the following applications:
1. Continuous or on-demand monitoring and report out of converter clock quality.
2. Indirect checking of power supply noise.
   a. This works on any supply that can introduce jitter to the clock, including the supply to power external oscillator.
   b. The converter's own power supplies can be checked by measuring the jitter from the internal RC oscillator.
3. Environmental sensing.
   a. Factors such as EMC and vibration can impact clock jitter. Measuring jitter can reveal additional insights on the operating environment.
   b. The idea can be extended to create a ‘virtual sensor’.
4. Used to create a dedicated jitter measurement device.
5. Create a sensor based on transducer that transduce a physical phenomena to jitter.

Finally, the present disclosure also provides using the jitter detection on a clock signal or an electronic component to develop a transducer apparatus.

In this regard, the present disclosure relates to a transducer, the transducer comprising:
a digital-to-analog converter, DAC, configured to be driven by an input signal from an environment, the input signal comprising jitter; a CT integrator configured to receive an output of the DAC; a quantizer configured to quantize an output of the CT integrator; and
a low pass filter configured to filter the quantized output such that the filtered output signal is directly proportional to the jitter in the input; wherein the transducer is configured to determine a property of the environment based on the filtered output signal.

The transducer, as described, may be utilized to detect various environmental conditions that impact clock jitter. Some of these conditions include electromagnetic compatibility (EMC), vibration, and other physical phenomena that may influence the clock signal or electronic component. By measuring the jitter, the transducer can provide valuable insights into the operating environment. The transducer may be further configured to sense one or more input signal parameters, the one or more input parameters comprising crosstalk, power supply noise, electromagnetic interference, EMI, vibration, shock, change in termination. This detection is not limited to these specific conditions, as the transducer's sensitivity to jitter allows it to be used as a ‘virtual sensor’ for a wide range of environmental factors that affect electronic signals.

As can be seen, all of the disclosure relating to FIGS. 4 to 9 are applicable to the transducer apparatus. The transducer apparatus provides a use case for the jitter detection methods and apparatus disclosed. Essentially, the transducer detects jitter on a clock signal or electronic component, wherein said clock signal or electronic signal is effected by environmental conditions.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.”

The words “coupled” or “connected” or “tied”, as generally used herein, refer to two or more elements or nodes that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list.

It will be understood that the above list is non-exhaustive, and that the method and system described herein is applicable to many technical problem domains to which machine learning models may be applied.

Various modifications, whether by addition, substitution, or deletion will be apparent to the intended reader to provide further examples of the present disclosure, any and all of which are intended to be encompassed by the appended claims.

### Numbered Aspects

By way of non-limiting example, some aspects of the disclosure are set out in the following numbered clauses.
Numbered Clause 1: A method of detecting jitter on a clock signal, the method comprising: operating a digital-to-analog converter, DAC, with a clock signal, the clock signal having noise comprising jitter to be detected; feeding an output of the DAC to an input of a CT integrator; quantizing a signal generated from the output of the CT integrator; filtering, by a low pass filter, the quantized signal such that the filtered output signal is directly proportional to the jitter in the clock signal; and detecting jitter based on the filtered output signal.
Numbered Clause 2: The method of clause 1, driving the input of the DAC using an output of an analog-to-digital converter, ADC.
Numbered Clause 3: The method of any preceding clause, wherein an average of the DAC output is zero at the input of the CT integrator when clock signal comprises no jitter or wherein an average of the DAC output deviated from zero by a known offset at the input of the CT integrator.
Numbered Clause 4: The method of any preceding clause, further comprising processing the filtered output signal to determine the presence of jitter and/or a quantity of jitter in the clock signal.
Numbered Clause 5: The method of any preceding clause, further comprising verifying that the clock signal comprises a predetermined level of jitter based on measuring an amplitude of the filtered output signal.
Numbered Clause 6: The method of any preceding clause, further comprising generating a confidence coefficient using the filtered output signal indicative of the level of jitter present in the clock signal.
Numbered Clause 7: The method of any preceding clause, wherein the filtering comprises digital filtering.
Numbered Clause 8: The method of any preceding clause, further comprising removing quantization noise from the filtered output signal.
Numbered Clause 9: The method of any preceding clause, the method further comprising processing the filtered output signal to find a root mean square, RMS, value.
Numbered Clause 10: The method of any preceding clause, further comprising averaging the filtered output signal using integration.
Numbered Clause 11: The method of any preceding clause, further comprising applying a scale factor to express the output as a clock jitter level in time, frequency or phase units.
Numbered Clause 12: The method of any preceding clause, wherein the method comprises implementing a CT sigma delta modulator and shorting an input pin of the CT sigma delta modulator such that the input to the CT sigma delta modulator is zero.
Numbered Clause 13: The method of clause 12, wherein shorting the input of the CT integrator causes a charge from the DAC to be pinned to zero such that an output of an ADC matches the input of the CT integrator.
Numbered Clause 14: The method of clause 13, further comprising converting the clock signal into current pulses of duration, Ts, and amplitude

$$\frac{+}{-} \frac{{V}_{R E F}}{R}$$

causing charge packets of

$$\frac{+}{-} \frac{{V}_{R E F} * {T}_{s}}{R}$$

to be injected into the CT integrator, wherein R is a resistance value of the DAC and VREF is a reference voltage of the electronic component.
Numbered Clause 15: The method of clause 14, the method further comprising: introducing a further error charge signal into the CT integrator.
Numbered Clause 16: The method of any of clauses 1 to 11, wherein the method comprises feeding a square wave input signal to the input pin of the CT integrator.
Numbered Clause 17: The method of clause 16, wherein the method comprises modulating the square wave input using the CT integrator.
Numbered Clause 18: An apparatus for detecting jitter on a clock signal, the apparatus comprising: a first digital-to-analog converter, DAC, configured to be operated by a clock signal, the clock signal comprising jitter to be detected; a CT integrator configures to receive an output from the first DAC; a quantizer configured to quantize a signal generated from the output of the CT integrator; and a low pass filter configured to filter the quantized signal such that the filtered output signal is directly proportional to the jitter in the clock signal.
Numbered Clause 19: The apparatus of clause 18, the apparatus further comprising a second DAC coupled to an input of the CT integrator, wherein the second DAC is a continuous time DAC.
Numbered Clause 20: The apparatus of any of clauses 18 to 19, the apparatus further comprising an analog-to-digital converter, ADC, wherein the ADC is coupled between the CT integrator and the first DAC and an output of the ADC is fed back to an input of the first DAC.
Numbered Clause 21: The apparatus of clause 20, wherein an input pin of the CT integrator is configured to be shorted such that the input pin of the CT integrator is zero.
Numbered Clause 22: The apparatus of clause 21, wherein the DAC is configured to convert the clock signal into current pulses of duration, Tₛ, and amplitude

$$\frac{+}{-} \frac{{V}_{R E F}}{R}$$

causing charge packets of

$$\frac{+}{-} \frac{{V}_{R E F} * {T}_{s}}{R}$$

to be injected into the CT integrator, wherein R is a resistance value of the first DAC and VREF is a reference voltage of the electronic component.
Numbered Clause 23: The apparatus of clause 22, wherein the DAC is configured to introduce a further error charge signal into the CT integrator.
Numbered Clause 24: The apparatus of any of clauses 18 to 23, further comprising an electronic component, the electronic component being configured to supply the clock signal to the first DAC.
Numbered Clause 25: The apparatus of clause 24, wherein the electronic component and the CT integrator are arranged on the same die or package.
Numbered Clause 26: The apparatus of any of clauses 18 to 25, wherein the electronic component is one or more of an analog-to-digital converter, ADC, a digital-to-analog converter, DAC, a phase-locked loop, PLL, a Frequency Synthesizer, a field-programmable gate array, FPGA, a central processing unit, CPU, a microcontroller, MCU, a digital signal processor, DSP, a Network interface/transceiver, a wireless transceiver, a clock generators/buffer, an application-specific integrated circuit, ASIC, and a sensor.
Numbered Clause 27: The apparatus of any of clauses 18 to 25, wherein the ADC, first DAC and CT integrator are configured to form a continuous time delta sigma, CTSD, modulator.
Numbered Clause 28: The apparatus of clause 27, wherein the CTSD modulator is a first order CTSD modulator.
Numbered Clause 29: A transducer, the transducer comprising: a digital-to-analog converter, DAC, configured to be driven by an input signal from an environment, the input signal comprising jitter; a CT integrator configured to receive an output of the DAC; a quantizer configured to quantize an output of the CT integrator; and a low pass filter configured to filter the quantized output such that the filtered output signal is directly proportional to the jitter in the input; wherein the transducer is configured to determine a property of the environment based on the filtered output signal.
Numbered Clause 30: The transducer of clause 29, wherein the transducer is further configured to sense one or more input signal parameters, the one or more input parameters comprising crosstalk, power supply noise, electromagnetic interference, EMI, vibration, shock, change in termination.

1. A method of detecting jitter on a clock signal, the method comprising:
operating a digital-to-analog converter, DAC, with a clock signal, the clock signal having noise comprising jitter to be detected;
feeding an output of the DAC to an input of a CT integrator;
quantizing a signal generated from the output of the CT integrator;
filtering, by a low pass filter, the quantized signal such that the filtered output signal is directly proportional to the jitter in the clock signal; and
detecting jitter based on the filtered output signal.

2. The method of claim 1, operating the DAC using an output of an analog-to-digital converter, ADC.

3. The method of claim 1, wherein an average of the DAC output is zero at the input of the CT integrator when clock signal comprises no jitter or wherein an average of the DAC output deviated from zero by a known offset at the input of the CT integrator.

4. The method of claim 1, comprising processing the filtered output signal to determine a presence of jitter and/or a quantity of jitter in the clock signal.

5. The method of claim 1, comprising verifying that the clock signal comprises a predetermined level of jitter based on measuring an amplitude of the filtered output signal.

6. The method of claim 1, comprising generating a confidence coefficient using the filtered output signal indicative of a level of jitter present in the clock signal.

7. The method of claim 1, wherein the filtering comprises digital filtering.

8. The method of claim 1, comprising removing quantization noise from the filtered output signal.

9. The method of claim 1, the method further comprising one or more of:
processing the filtered output signal to find a root mean square, RMS, value;
averaging the filtered output signal using integration.

10. The method of claim 1, comprising applying a scale factor to express the filtered output signal as a clock jitter level in time, frequency or phase units.

11. The method of claim 1, wherein the method comprises implementing a CT sigma delta modulator and shorting an input pin of the CT sigma delta modulator such that the input to the CT sigma delta modulator is zero.

12. The method of claim 1, wherein the method comprises feeding a square wave input signal to an input pin of the CT integrator, and optionally, wherein the method comprises modulating the square wave input using the CT integrator.

13. An apparatus for detecting jitter on a clock signal, the apparatus comprising:
a first digital-to-analog converter, DAC, configured to be operated by a clock signal from, the clock signal comprising jitter to be detected;
a CT integrator configures to receive an output from the first DAC;
a quantizer configured to quantize a signal generated from the output of the CT integrator; and
a low pass filter configured to filter the quantized signal such that the filtered output signal is directly proportional to the jitter in the clock signal.

14. The apparatus of claim 13, the apparatus comprising a second DAC coupled to an input of the CT integrator, wherein the second DAC is a continuous time DAC.

15. The apparatus of claim 13, the apparatus comprising an analog-to-digital converter, ADC, wherein the ADC is coupled between the CT integrator and the first DAC and an output of the ADC is fed back to an input of the first DAC, and optionally, wherein an input pin of the CT integrator is configured to be shorted such that the input pin of the CT integrator is zero.

16. The apparatus of claim 13, comprising an electronic component, the electronic component being configured to supply the clock signal to operate the first DAC, and optionally, wherein the electronic component and the CT integrator are arranged on the same die or package.

17. The apparatus of claim 13, comprising an electronic component, wherein the electronic component is one or more of an analog-to-digital converter, ADC, a digital-to-analog converter, DAC, a phase-locked loop, PLL, a Frequency Synthesizer, a field-programmable gate array, FPGA, a central processing unit, CPU, a microcontroller, MCU, a digital signal processor, DSP, a Network interface/transceiver, a wireless transceiver, a clock generators/buffer, an application-specific integrated circuit, ASIC, and a sensor.

18. The apparatus of claim 13, comprising an analog-to-digital converter, ADC, wherein the ADC, first DAC and CT integrator are configured to form a continuous time delta sigma, CTSD, modulator.

19. A transducer, the transducer comprising:
a digital-to-analog converter, DAC, configured to be driven by an input signal from an environment, the input signal comprising jitter;
a CT integrator configured to receive an output of the DAC;
a quantizer configured to quantize an output of the CT integrator; and
a low pass filter configured to filter the quantized output such that the filtered output signal is directly proportional to the jitter in the input;
wherein the transducer is configured to determine a property of the environment based on the filtered output signal.

20. The transducer of claim 19, wherein the transducer is configured to sense one or more input signal parameters, the one or more input parameters comprising crosstalk, power supply noise, electromagnetic interference, EMI, vibration, shock, change in termination.
